(19) United States
(12) Patent Application Publication
(10) Pub. No.: US 2014/0020628 A1
(43) Pub. Date: Jan. 23, 2014

(54) SHADOW MASK MODULE AND ORGANIC VAPOR DEPOSITION APPARATUS AND THERMAL EVAPORATION APPARATUS USING THE SAME

(71) Applicants: WINTEK CORPORATION, Taichung City (TW); Wintek (China) Technology Ltd., Dongguan City (CN)

(72) Inventors: Wen-Chun Wang, Taichung City (TW); Hen-Ta Kang, Taichung City (TW); Kuo-Chang Su, Taichung City (TW); Siang-Lin Huang, Taichung City (TW)

(73) Assignees: WINTEK CORPORATION, Taichung City (TW); Wintek (China) Technology Ltd., Dongguan City (CN)

(21) Appl. No.: 13/943,799

(22) Filed: Jul. 17, 2013

(30) Foreign Application Priority Data
Jul. 17, 2012 (TW) 101125687

(51) Int. Cl. H01L 21/02

(52) U.S. Cl. CPC H01L 21/02104
USPC 118/721

(57) ABSTRACT

The present invention provides a shadow mask module and an organic vapor deposition apparatus and a thermal evaporation apparatus using the same. The shadow mask module is disposed between a gas outlet and a substrate, and includes a pixel mask and a thermal resist mask. The pixel mask is disposed between the gas outlet and the substrate, and includes a plurality of first openings. The thermal resist mask is disposed between the gas outlet and the pixel mask, and includes a plurality of second openings. Each second opening is disposed corresponding to at least one of the first openings.

### BACKGROUND OF THE INVENTION

1. Field of the Invention

The present invention relates to a shadow mask module, an organic vapor deposition apparatus using the same and a thermal evaporation apparatus using the same, and more particularly, to a shadow mask module having a thermal resist mask and an organic vapor deposition apparatus and a thermal evaporation apparatus using the same.

2. Description of the Prior Art

In the conventional method for manufacturing the organic light-emitting diode display, an organic light-emitting layer used to generate light is formed by a thermal evaporation or an organic vapor deposition method, and a pixel mask is disposed between a gas shower head of an evaporation source or an organic vapor deposition apparatus and a substrate. Furthermore, the organic vapor deposition apparatus inputs inert gas to carry an organic material, and the inert gas is transferred to the gas shower head through a tube and sprays out from the gas shower head. Since a required layout pattern of a pixel structure is the same as a predetermined opening pattern of the pixel mask, the sprayed organic material can be deposited on the substrate based on the predetermined opening pattern of the pixel mask, and the deposited organic material forms the organic light-emitting layer.

However, during transferring the inert gas and the carried organic material to the gas shower head, it is required to maintain a temperature of the inert gas and the carried organic material within about 200 to 300 degrees Celsius to avoid the gas shower head used for spraying the organic material being blocked. In order to avoid this problem, the organic vapor deposition apparatus would heat the inert gas and the carried organic material at the gas shower head to increase the temperature about 10 degrees Celsius. Since the temperature of the inert gas and the carried organic material is high, the temperature of the inert gas and the carried organic material is still over 60 to 70 degrees Celsius while reaching the pixel mask. Thus, the pixel mask is expanded thermally because of the temperature of the inert gas and the carried organic material. Also, the pixel mask is formed with metal so as to have higher expansion coefficient. Accordingly, the size of the predetermined opening pattern of the pixel mask is easily changed by the thermal expansion, and the alignment of the predetermined opening pattern of the pixel mask to the substrate is easily shifted. For this reason, the formed layout pattern of the pixel structure is also changed with the change of the size of the predetermined opening pattern, and the product yield and quality are reduced. Moreover, in order to increase material utilization ratio, the organic vapor deposition apparatus further reduces a distance between the gas outlet for outputting the inert gas and the carried organic material and the substrate, so that the pixel mask is more easily affected by the temperature of the inert gas and the carried organic material. Similarly, the thermal evaporation apparatus also has this problem.

Therefore, it is an objective in this field to reduce the affect of the temperature of the inert gas and the carried organic material to the pixel mask to increase accuracy in alignment between the pixel mask and the substrate.

### SUMMARY OF THE INVENTION

It is one of the objectives of the present invention to provide a shadow mask module, an organic vapor deposition apparatus using the same and a thermal evaporation apparatus using the same to reduce the affect of the gas temperature to the pixel mask to increase accuracy in alignment between the pixel mask and the substrate.

According to an aspect of the present invention, a shadow mask module disposed between a gas outlet and a substrate is provided. The shadow mask module includes a pixel mask and a thermal resist mask. The pixel mask is disposed between the gas outlet and the substrate, and the pixel mask includes a plurality of first openings. The thermal resist mask is disposed between the gas outlet and the pixel mask, and the thermal resist mask includes a plurality of second openings, wherein each second opening is disposed corresponding to at least one of the first openings.

According to another aspect of the present invention, an organic vapor deposition apparatus used for depositing an organic material on a substrate is provided. The organic vapor deposition apparatus includes a gas source, a control valve, a gas shower head, a tube, and a shadow mask module. The gas source is used for providing a gas. The control valve is connected to an outlet of the gas source and used for controlling a flow of the gas of the gas source and a switch of the gas source. The gas shower head is aimed at the substrate. An end of the tube is connected to the control valve, and another end of the tube is connected to the gas shower head. The tube is used for transferring the gas to the gas shower head. The shadow mask module is disposed between the gas shower head and the substrate, and the shadow mask module includes a pixel mask and a thermal resist mask. The pixel mask is disposed between the gas shower head and the substrate, and the pixel mask includes a plurality of first openings. The thermal resist mask is disposed between the gas shower head and the pixel mask, and the thermal resist mask includes a plurality of second openings, wherein each second opening is disposed corresponding to at least one of the first openings.

According to another aspect of the present invention, a thermal evaporation apparatus used for evaporating an organic material on a substrate is provided. The thermal evaporation deposition apparatus includes an evaporation source and a shadow mask module. The evaporation source is used for evaporating the organic material. The shadow mask module is disposed between the evaporation source and the substrate, and the shadow mask module includes a pixel mask and a thermal resist mask. The pixel mask is disposed between the evaporation source and the substrate, and the pixel mask includes a plurality of first openings. The thermal resist mask is disposed between the evaporation source and the pixel mask, and the thermal resist mask includes a plurality of second openings, wherein each second opening is disposed corresponding to at least one of the first openings.

The thermal resist mask of the shadow mask module in the present invention is disposed between the gas outlet and the pixel mask, so that the thermal resist mask can be used to insulate a part of the gas with a temperature over a certain degree from being in contact with the pixel mask and reduce the heat of the gas conducted to the pixel mask. Thus, the temperature of the pixel mask can be prevented from increasing, and the pixel mask can be prevented from being thermally expanded to exceed a required accuracy range because of being directly in contact with the gas. Therefore, the accuracy in alignment between the pixel mask and the substrate can be increased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a shadow mask module according to a first preferred embodiment of the present invention.

FIG. 2 is a schematic diagram illustrating a top view of the shadow mask module according to the first preferred embodiment of the present invention.

FIG. 3 is a schematic diagram illustrating a cross-sectional view of a shadow mask module according to a second preferred embodiment of the present invention.

FIG. 4 is a schematic diagram illustrating a cross-sectional view of a shadow mask module according to a third preferred embodiment of the present invention.

FIG. 5 is a schematic diagram illustrating a cross-sectional view of a shadow mask module according to a fourth preferred embodiment of the present invention.

FIG. 6 is schematic diagram illustrating a shadow mask module according to a fifth preferred embodiment of the present invention.

FIG. 7 is a schematic diagram illustrating a top view of a shadow mask module according to a sixth preferred embodiment of the present invention.

FIG. 8 is a top view of a shadow mask module according to a seventh preferred embodiment of the present invention.

FIG. 9 is a schematic diagram illustrating an organic vapor deposition apparatus according to a preferred embodiment of the present invention.

FIG. 10 is a schematic diagram illustrating a thermal evaporation apparatus according to another preferred embodiment of the present invention.

### DETAILED DESCRIPTION

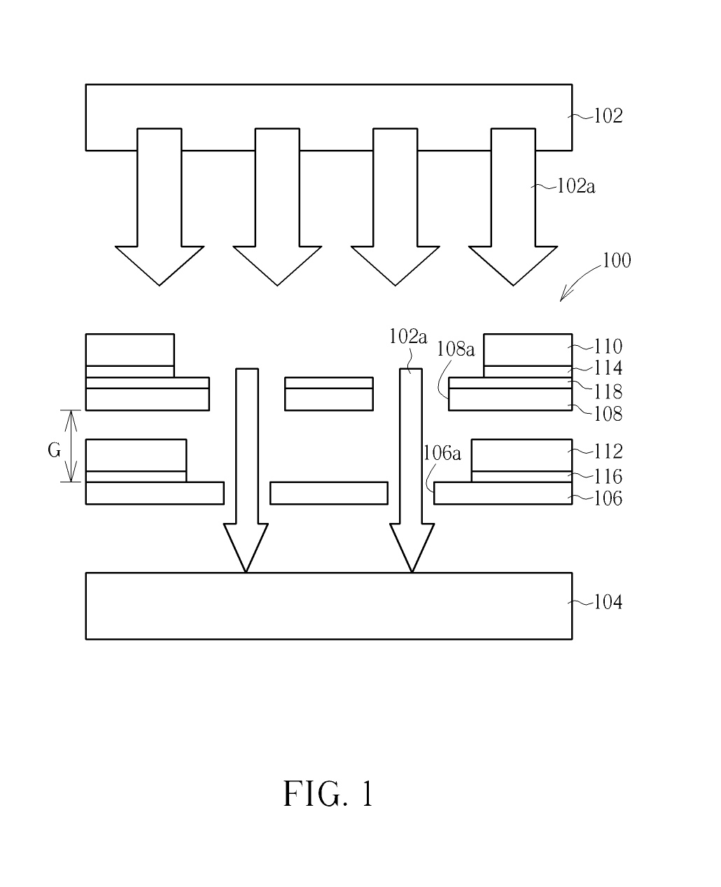

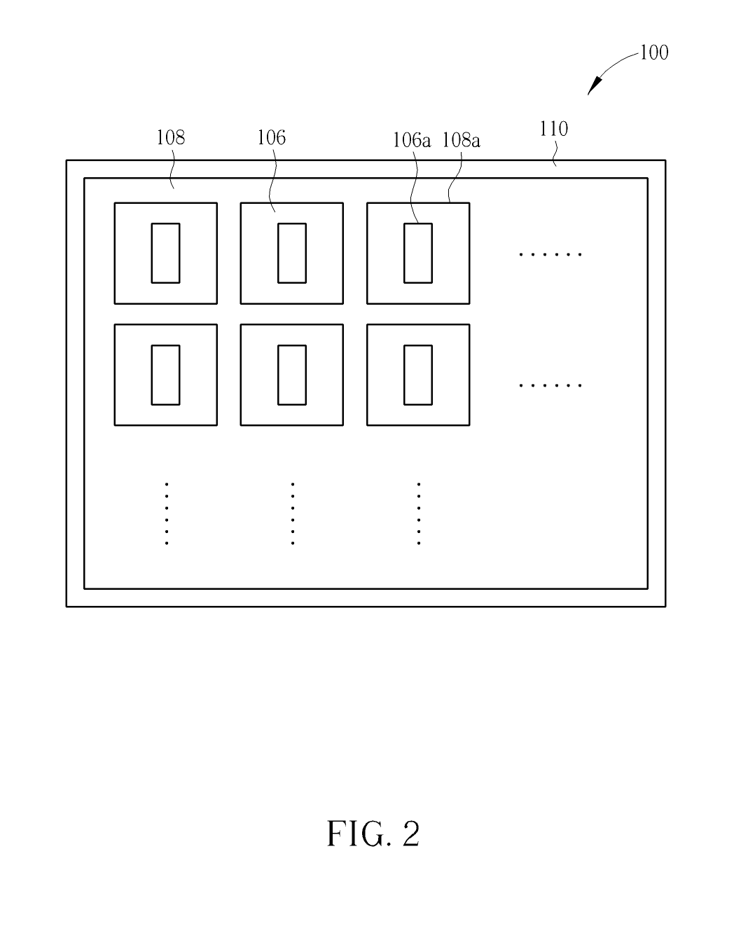

Please refer to FIGS. 1 and 2. FIG. 1 is a schematic diagram illustrating a cross-sectional view of a shadow mask module according to a first preferred embodiment of the present invention, and FIG. 2 is a schematic diagram illustrating a top view of the shadow mask module according to the first preferred embodiment of the present invention. As shown in FIGS. 1 and 2, the shadow mask module 100 is disposed between a gas outlet 102 and a substrate 104. In this embodiment, the gas outlet 102 may be a gas shower head of an organic vapor deposition apparatus or an evaporation source of a thermal evaporation apparatus for providing a gas 102a including a required organic material and spraying the gas 102a out at a certain rate. The gas outlet of the present invention is not limited to this, and may be different with the variants of the organic vapor deposition apparatus. Also, the gas 102a in this embodiment may include inert gas and organic material, and the inert gas is used to carry the organic material, but the present invention is not limited herein. The gas of the present invention may be determined according to the used organic vapor deposition method, and substantially include the organic material. The substrate 104 in this embodiment may be an array substrate having array circuits, but the present invention is not limited to this. The substrate of the present invention may be determined according to the required organic material.

In addition, the shadow mask module 100 in this embodiment includes a pixel mask 106, a thermal resist mask 108, a first frame 110, and a second frame 112. The pixel mask 106 is disposed between the gas outlet 102 and the substrate 104 and used as a mask for forming an organic material layer (not shown in figures). The thermal resist mask 108 is disposed between the gas outlet 102 and the pixel mask 106, and there is a gap G between the thermal resist mask 108 and the pixel mask 106. In this embodiment, the pixel mask is a metal mesh structure, and includes a plurality of first openings 106a, and each first opening is substantially the same as a size of a pixel structure of the array substrate, so that the organic material layer formed by the gas 102a passing through each first opening 106a to be deposited on the substrate 104 can have the same size as an aperture of the pixel structure and can serve as a light-emitting layer of each pixel structure. The organic material layer of the present invention is not limited to be the light-emitting layer of each pixel structure. The pixel mask 106 can include pure metal or metal alloy, so that the pixel mask 106 can be formed to have each first opening 106a having the same size as the aperture of each pixel structure, but the present invention is not limited to this. Furthermore, the thermal resist mask 108 includes a plurality of second openings 108a, and each second opening 108a is disposed corresponding to at least one first opening 106a. Also, the thermal resist mask 108 may include metal or glass, and preferably include a material with lower thermal expansion coefficient. In this embodiment, each second opening 108a is disposed corresponding to each first opening 106a, and each second opening 108a is larger than each first opening 106a. Furthermore, each first opening 106a is located in each second opening 108a along a projecting direction perpendicular to the thermal resist mask 108. Thus, when the gas 102a sprays toward the shadow mask module 100 along a direction perpendicular to the shadow mask module 100, the shadow mask module 100 is used as a mask for allowing the gas 102a to pass through, and the organic material layer is formed on the substrate 104. Moreover, a part of the gas 102a may be stopped by the thermal resist mask 108, and the other part of the gas 102a may pass through the second openings 108a first. Then, since each second opening 108a is larger than each first opening 106a along the projecting direction perpendicular to the thermal resist mask 108, a part of the gas 102a passing through the second openings 108a may be stopped by the pixel mask 106, and the other part of the gas 102a passing through the second openings 108a may pass through the first openings 106a and be deposited on the substrate 104. Accordingly, without affecting the size of the deposited organic material layer, the thermal resist mask 108 can insulate a part of the gas 102a with an over high temperature from being in contact with the pixel mask 106. Thus, the temperature of the pixel mask 106 can be prevented from increasing, and the pixel mask 106 can be prevented from being thermally expanded to exceed a required accuracy range because of being directly in contact with the gas 102a.

In this embodiment, the first frame 110 is disposed between the thermal resist mask 108 and the gas outlet 102, and the second frame 112 is disposed between the pixel mask 106 ad the thermal resist mask 108. Also, the thermal resist mask 108 is fixed on the first frame 110, and the pixel mask 106 is fixed on the second frame 112, so that the gap G between the thermal resist mask 108 and the pixel mask 106 can be controlled by adjusting a position of the first frame 110 and a position of the second frame 112. In addition, the first frame 110 and the second frame 112 in this embodiment are ring-shaped, and have an opening respectively larger than a distribution range of the first openings 106a and a distribution range of the second openings 108a so as to avoid shielding the gas 102a passing through the first openings 106a. The first frame 110 is fixed with an edge part of the thermal resist mask 108, and the second frame 112 is fixed with an edge part of the pixel mask 106, so that the gas 102a passing through the first openings 106a is not stopped by the first frame 110. The first frame and the second frame of the present invention are not limited to this. In other embodiments of the present invention, the first frame or the second frame also may be a frame with another geometric shape, such as stripe-shaped, but is not limited herein.

In addition, the shadow mask module 100 may optionally further include a first thermal insulating adhesive layer 114 and a second thermal insulating adhesive layer 116 to reduce the heat of the gas conducted to the pixel mask 106 through the thermal resist mask 108, the first frame 110 and the second frame 112. In this embodiment, the first thermal insulating adhesive layer 114 is disposed between the thermal resist mask 108 and the first frame 110 and used for reducing the heat of the first frame 110 conducted to the thermal resist mask 108. The second thermal insulating adhesive layer 116 is disposed between the pixel mask 106 and the second frame 112 and used for reducing the heat of the second frame 112 conducted to the pixel mask 106. Furthermore, the shadow mask module 100 also can use a known method, such as welding, screw or other fixing device to fix the thermal resist mask 108 on the first frame 110 and fix the pixel mask 106 on the second frame 112.

Moreover, the shadow mask module 100 may optionally further include a thermal insulating layer 118 disposed on a surface of the thermal resist mask 108 opposite to the gas outlet 102 and used for stopping the heat of the gas 102a from conducting to the thermal resist mask 108. In other embodiments of the present invention, the shadow mask module may optionally further include another thermal insulating layer disposed on a surface of the pixel mask opposite to the thermal resist mask to reduce the heat conducted to the pixel mask.

It should be noted that the thermal resist mask 108 of the shadow mask module 100 in this embodiment is disposed between the gas outlet 102 and the pixel mask 106, so that the thermal resist mask 108 can be used to insulate a part of the gas 102a with a temperature over a certain degree from being in contact with the pixel mask 106 and reduce the heat of the gas 102a conducted to the pixel mask 106. Thus, the temperature of the pixel mask 106 including metal material can be prevented from increasing, and the pixel mask 106 including metal material can be prevented from being thermally expanded to exceed a required accuracy range because of being directly in contact with the gas 102a. Therefore, the accuracy in alignment between the pixel mask 106 and the substrate 104 can be increased to avoid an error in aligning the formed organic material layer to the array substrate, and the yield of manufacturing the organic display panel can be raised.

The shadow mask module of the present invention is not limited to the above-mentioned embodiment. The following description continues to detail the other embodiments or modifications, and in order to simplify and show the difference between the other embodiments or modifications and the above-mentioned embodiment, the same numerals denote the same components in the following description, and the same parts are not detailed redundantly.

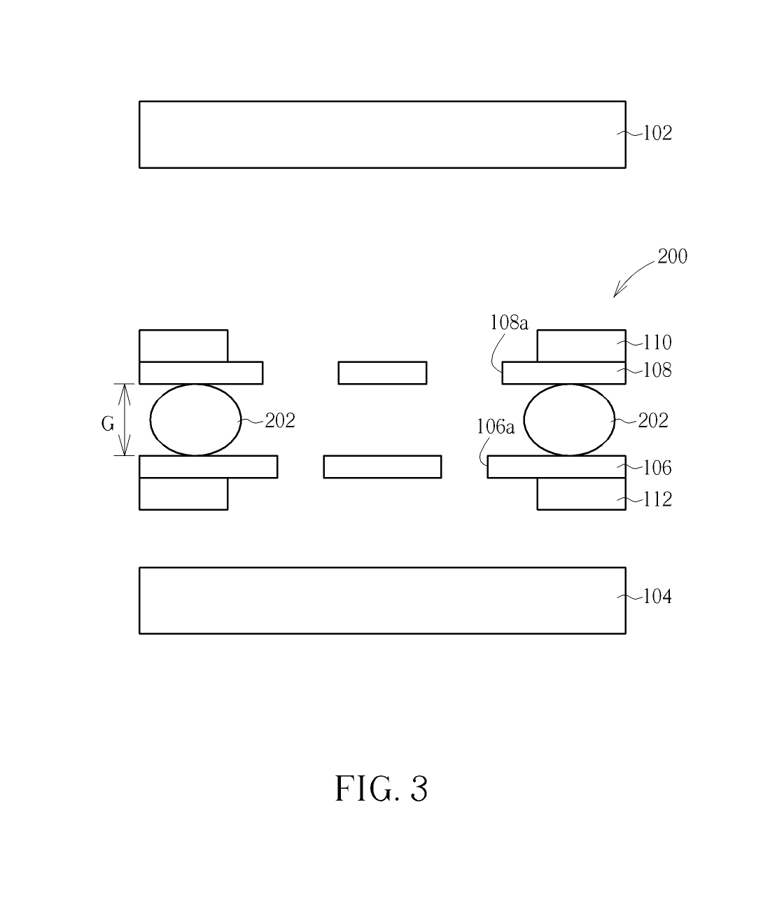

Please refer to FIG. 3, which is a schematic diagram illustrating a cross-sectional view of a shadow mask module according to a second preferred embodiment of the present invention. As shown in FIG. 3, as compared with the first embodiment, the second frame 112 of the shadow mask module 200 in this embodiment is disposed between the pixel mask 106 and the substrate 104, and the pixel mask 106 is fixed on the second frame 112. Furthermore, the shadow mask module 200 may optionally further include two spacers 202 disposed between the thermal resist mask 108 and the pixel mask 106, and the spacers 202 do not overlap the first openings 106a and the second openings 108a so as to avoid stopping the gas 102a passing through the first openings 106a. It should be noted that the first frame 110 and the second frame 112 can be adjusted to the thermal resist mask 108 and the pixel mask 106 being in contact with the spacers 202. Accordingly, the gap G between the pixel mask 106 and the thermal resist mask 108 can be fixed to be the same as the height of the spacers 202. Thus, the gap G between the pixel mask 106 and the thermal resist mask 108 can be adjusted according to the size of the spacers 202 in the shadow mask module 200 of this embodiment, and the gap G between the pixel mask 106 and the thermal resist mask 108 can be avoided being limited with a thickness of the second frame 112. The number of the spacers of the present invention is not limited to the above-mentioned number, and the shadow mask of the present invention may also include one spacer or over two spacers. In the other embodiments of the present invention, the shadow mask module may further include a first thermal insulating adhesive layer disposed between the thermal resist mask and the first frame, a second thermal insulating adhesive layer disposed between the pixel mask and the second frame, and a thermal insulating layer disposed on a surface of the thermal resist mask opposite to the gas outlet, but the present invention is not limited to this.

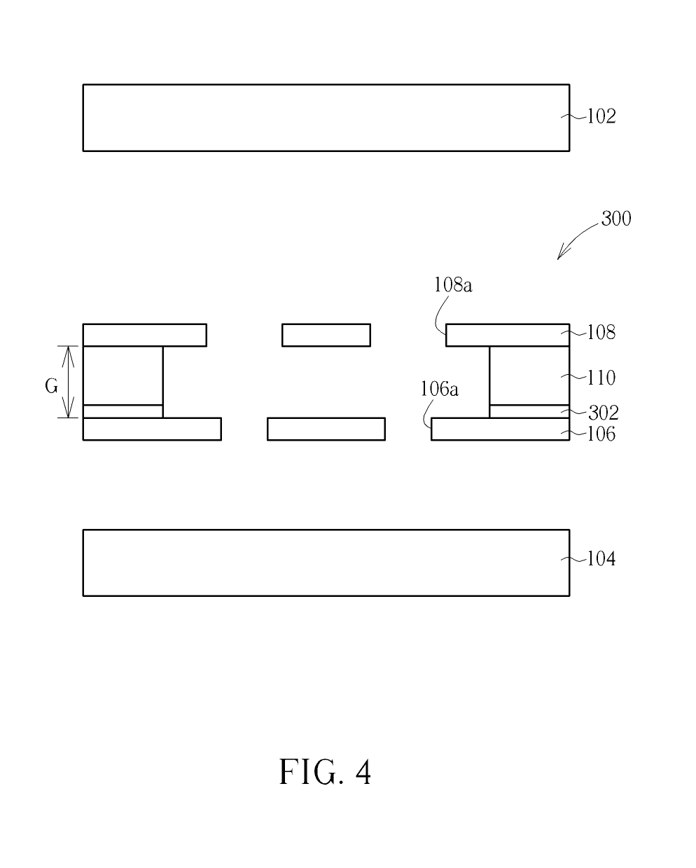

Please refer to FIG. 4, which is a schematic diagram illustrating a cross-sectional view of a shadow mask module according to a third preferred embodiment of the present invention. As shown in FIG. 4, as compared with the first embodiment, the shadow mask module 300 only includes the first frame 110, but does not include the second frame and the second thermal insulating adhesive layer. The first frame 110 is disposed between the thermal resist mask 108 and the pixel mask 106, and the pixel mask 106 also is fixed on the first frame 110, so that the thermal resist mask 108 and the pixel mask 106 can be fixed on a top surface and a bottom surface of the first frame 110 respectively. Accordingly, the gap G between the pixel mask 106 and the thermal resist mask 108 may be fixed to be the same as the thickness of the first frame 110, and the gap G between the pixel mask 106 and the thermal resist mask 108 may be adjusted according to the thickness of the first frame 110. Furthermore, the shadow mask module 300 of this embodiment may optionally further include a third thermal insulating adhesive layer 302 disposed between the pixel mask 106 and the first frame 110 and used for reducing the heat conducted between the pixel mask 106 and the first frame 110. In other embodiments of the present invention, the shadow mask module may further include a first thermal insulating adhesive layer disposed between the thermal resist mask and the first frame, and a thermal insulating layer disposed on the surface of the thermal resist mask opposite to the gas outlet, but the present invention is not limited herein.

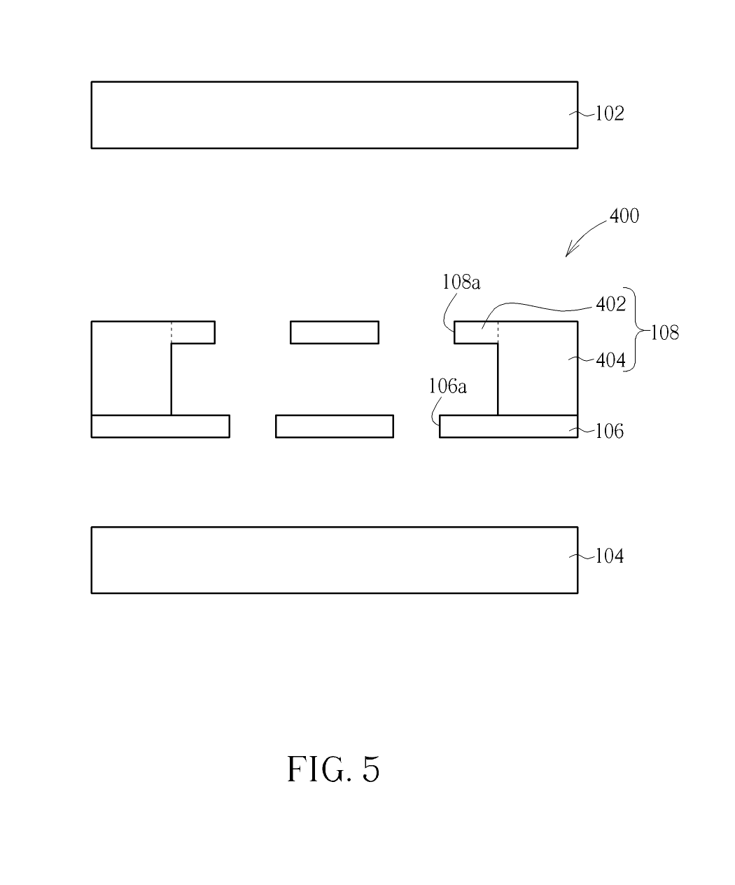

Please refer to FIG. 5, which is a schematic diagram illustrating a cross-sectional view of a shadow mask module according to a fourth preferred embodiment of the present invention. As shown in FIG. 5, as compared with the third embodiment, the thermal resist mask and the first thermal insulating adhesive layer of the shadow mask module 400 in this embodiment are formed as a unity. In other words, the shadow mask module 400 does not have the first frame and the first thermal insulating adhesive layer, and the thermal resist mask 108 includes a mask part 402 and a frame part 404. A thickness of the frame part 404 is larger than a thickness of the mask part 402, and the mask part 402 includes a plurality of second openings 108a disposed corresponding to at least one first opening 106a. The pixel mask 106 is fixed on the frame part 404. In other embodiments of the present invention, the shadow mask module may further include a third thermal insulating adhesive layer disposed between the pixel mask and the frame part, and a thermal insulating layer disposed on the surface of the thermal resist mask opposite to the gas outlet, but the present invention is not limited herein.

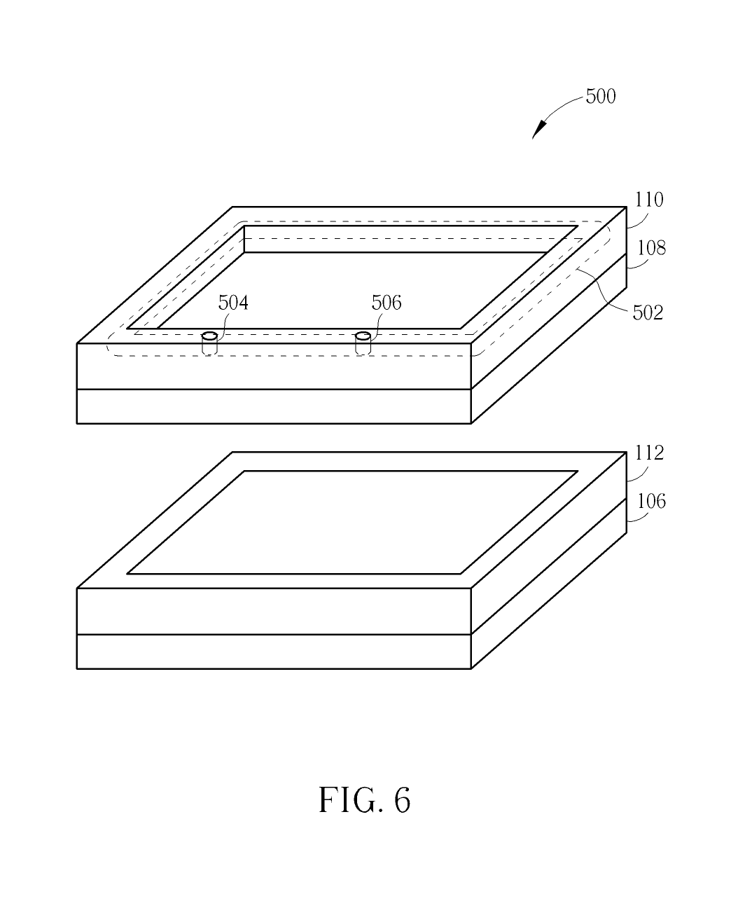

Please refer to FIG. 6, which is schematic diagram illustrating a shadow mask module according to a fifth preferred embodiment of the present invention. As shown in FIG. 6, as compared with the first embodiment, the shadow mask module 500 of this embodiment further include a cooling tube disposed in the first frame 110 and used for transferring a cooling material. Accordingly, the shadow mask module 500 can conduct the heat of the first frame 110 to the cooling material through transferring the cooling material in the cooling tube so as to cool the first frame 110. The shadow mask module 500 of this embodiment may further include a cooling material inlet 504 and a cooling material outlet 506. The cooling material inlet 504 can be used for inputting the cooling material without thermally exchanging with the first frame 110 to the cooling tube 502, and the cooling material outlet 506 can be used for discharging the cooling material with the heat from the first frame 110, so that the first frame 110 can be cooled down. In other embodiments of the present invention, the shadow mask module may further include a first thermal insulating adhesive layer disposed between the thermal resist mask and the first frame, a second thermal insulating adhesive layer disposed between the pixel mask and the second frame, and a thermal insulating layer disposed on the surface of the thermal resist mask opposite to the gas outlet, but the present invention is not limited herein. Also, the cooling tube may be disposed in the second frame or disposed in both the first frame and the second frame.

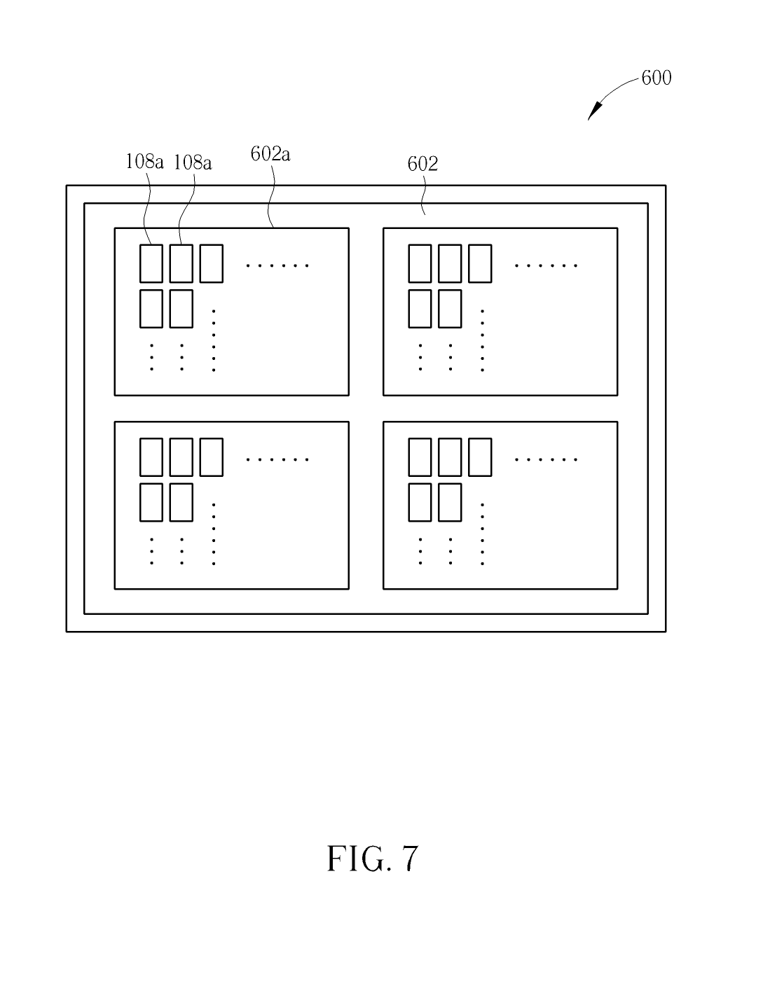

Please refer to FIG. 7, which is a schematic diagram illustrating a top view of a shadow mask module according to a sixth preferred embodiment of the present invention. As shown in FIG. 7, as compared with the first embodiment, the thermal resist mask 602 of the shadow mask module 600 in this embodiment is a common mask, and the common mask is a mask for defining material layers, such as common electrode, except pixel, and each second opening 602a of the thermal resist mask 602 is disposed corresponding to a plurality of the first openings 108a. Accordingly, a cost of an extra thermal resist mask can be saved in the shadow mask module 600 of this embodiment.

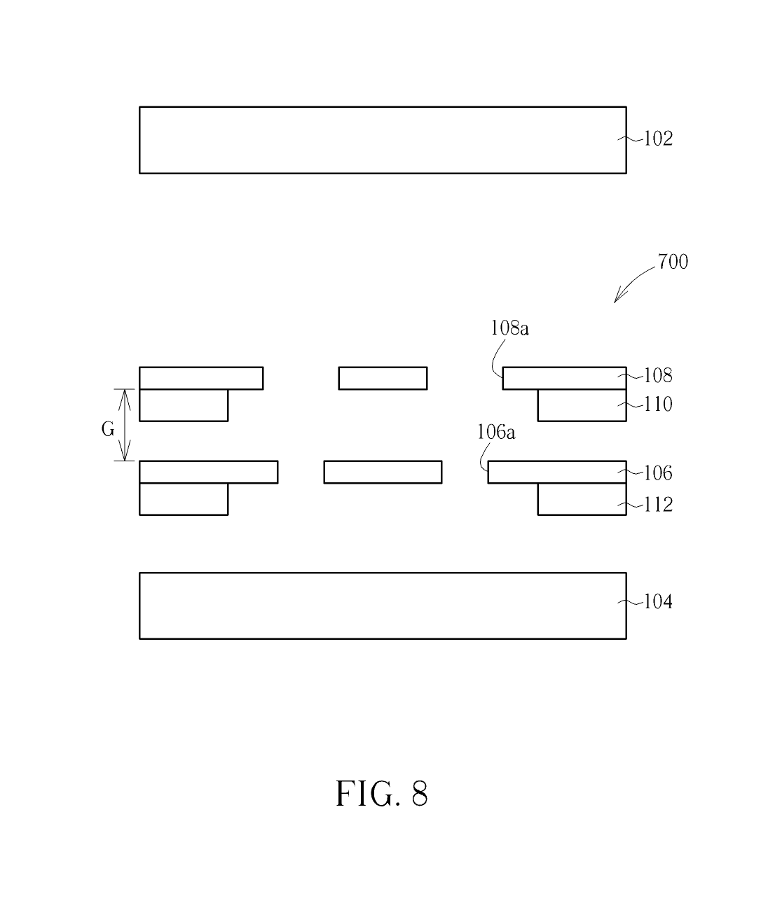

Please refer to FIG. 8, which is a top view of a shadow mask module according to a seventh preferred embodiment of the present invention. As shown in FIG. 8, as compared with the first embodiment, the first frame 110 and the second frame 112 of the shadow mask module 700 in this embodiment are respectively disposed on a bottom surface of the thermal resist mask 108 and a bottom surface of the pixel mask 106. That is to say that the first frame 110 is disposed between the thermal resist mask 108 and the pixel mask 106, and the second frame 112 is disposed between the pixel mask 106 and the substrate 104 in this embodiment. In other embodiments of the present invention, the shadow mask module may further include a first thermal insulating adhesive layer disposed between the thermal resist mask and the first frame, a second thermal insulating adhesive layer disposed between the pixel mask and the second frame, and a thermal insulating layer disposed on the surface of the thermal resist mask opposite to the gas outlet, but the present invention is not limited herein.

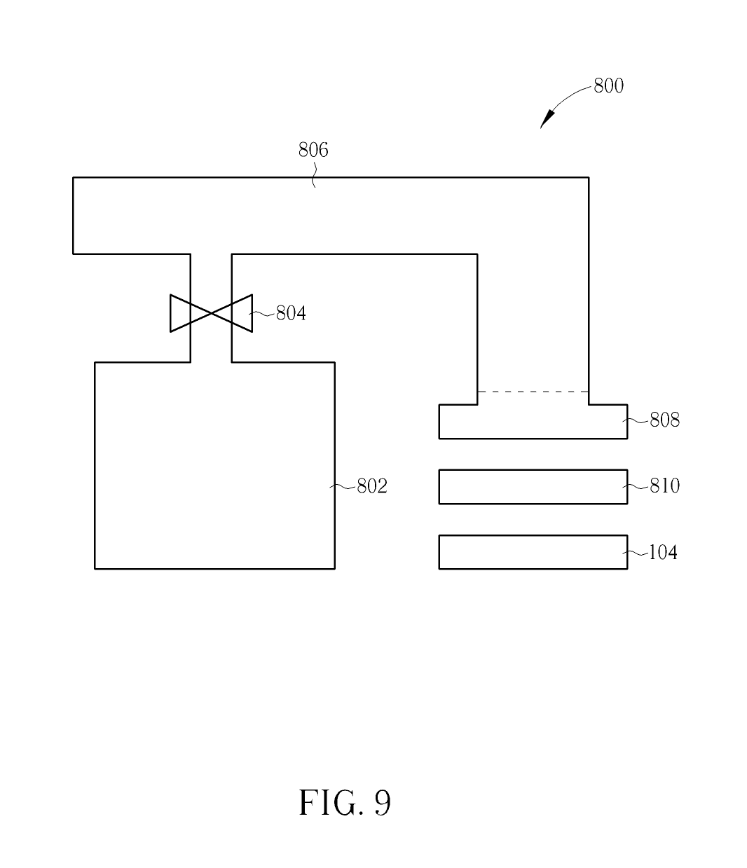

According to the shadow mask modules of the above-mentioned embodiments, the present invention further provides an organic vapor deposition apparatus. Please refer to FIG. 9, which is a schematic diagram illustrating an organic vapor deposition apparatus according to a preferred embodiment of the present invention. As shown in FIG. 9, in this embodiment, the organic vapor deposition apparatus 800 is used for depositing an organic material on the substrate 104, and includes a gas source 802, a control valve 804, a tube 806, a gas shower head 808, and a shadow mask module 810. The gas source 802 is used for providing a gas, such as organic material. The control valve 804 is connected to an outlet of the gas source 802 and used for controlling a flow of the gas of the gas source 802 and a switch of the gas source 802. An end of the tube 806 is connected to the control valve 804, and another end of the tube 806 is connected to the gas shower head 808. The tube is used for transferring the gas to the gas shower head 808. The gas shower head is aimed at the substrate 104. The shadow mask module 810 is disposed between the gas shower head 808 and the substrate 104. Accordingly, a part of the gas discharged from the gas shower head 808 can be stopped by the shadow mask module 810, and other part of the gas can be formed on the substrate 104. The shadow mask module 810 of this embodiment may be the shadow mask module of any one or a combination of any two of above-mentioned embodiments, and is not detailed redundantly.

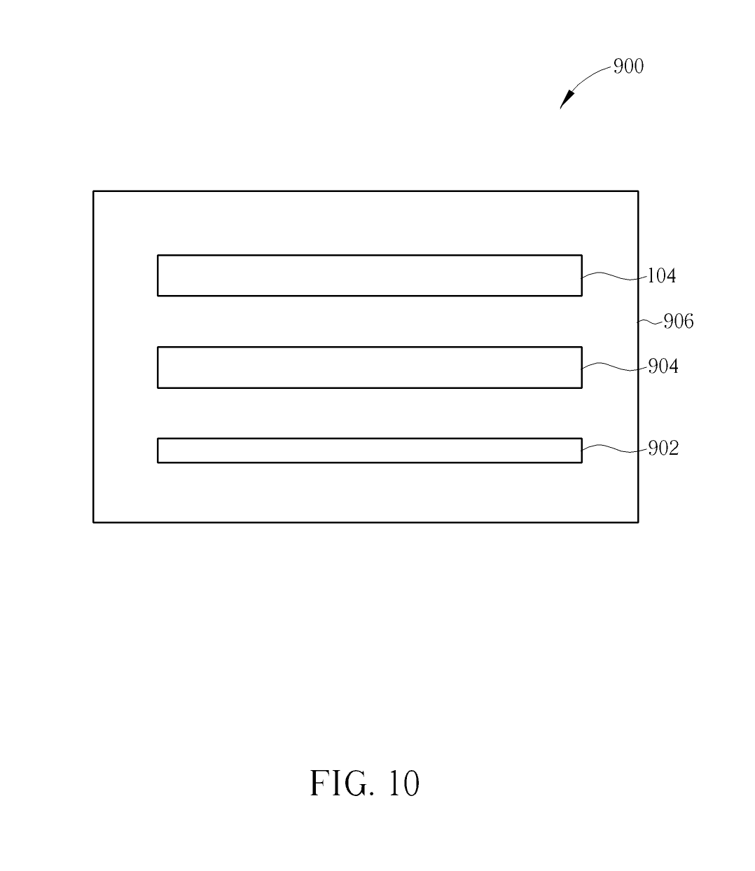

Please refer to FIG. 10, which is a schematic diagram illustrating a thermal evaporation apparatus according to another preferred embodiment of the present invention. As shown in FIG. 10, the thermal evaporation apparatus 900 of this embodiment is used for evaporating an organic material on the substrate 104, and includes an evaporation source 902, a shadow mask module 904, and a reaction chamber 906. The evaporation source 902, the shadow mask module 904 and the substrate 104 are disposed in the reaction chamber 906, and the shadow mask module 904 is disposed between the evaporation source 902 and the substrate 104. The evaporation source 902 of this embodiment is used for evaporating the organic material, so that the gas including the organic material can be formed on the substrate 104 through the shadow mask module 904. The shadow mask module 904 of this embodiment may be the shadow mask module of any one or a combination of any two of above-mentioned embodiments, and is not detailed redundantly.

In summary, the thermal resist mask of the shadow mask module in the present invention is disposed between the gas outlet and the pixel mask, so that the thermal resist mask can be used to insulate a part of the gas with a temperature over a certain degree from being in contact with the pixel mask and reduce the heat of the gas conducted to the pixel mask. Thus, the temperature of the pixel mask can be prevented from increasing, and the pixel mask can be prevented from being thermally expanded to exceed a required accuracy range because of being directly in contact with the gas. Therefore, the accuracy in alignment between the pixel mask and the substrate can be increased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A shadow mask module disposed between a gas outlet and a substrate, and the shadow mask module comprising:
a pixel mask disposed between the gas outlet and the substrate, and the pixel mask comprising a plurality of first openings; and
a thermal resist mask disposed between the gas outlet and the pixel mask, and the thermal resist mask comprising a plurality of second openings, wherein each second opening is disposed corresponding to at least one of the first openings.

2. The shadow mask module according to claim 1, further comprising a first frame, and the thermal resist mask is fixed on the first frame.

3. The shadow mask module according to claim 2, further comprising a first thermal insulating adhesive layer disposed between the thermal resist mask and the first frame.

4. The shadow mask module according to claim 2, further comprising a second frame, and the pixel mask being fixed on the second frame.

5. The shadow mask module according to claim 4, wherein the first frame is disposed between the thermal resist mask and the gas outlet, and the second frame is disposed between the pixel mask and the thermal resist mask.

6. The shadow mask module according to claim 4, wherein the first frame is disposed between the thermal resist mask and the pixel mask, and the second frame is disposed between the pixel mask and the substrate.

7. The shadow mask module according to claim 4, further comprising a second thermal insulating adhesive layer disposed between the pixel mask and the second frame.

8. The shadow mask module according to claim 4, wherein the first frame is disposed between the thermal resist mask and the gas outlet, and the second frame is disposed between the pixel mask and the substrate.

9. The shadow mask module according to claim 8, further comprising at least one spacer disposed between the thermal resist mask and the pixel mask, and the spacer being in contact with the thermal resist mask and the pixel mask.

10. The shadow mask module according to claim 2, wherein the pixel mask is fixed on the first frame, and the first frame is disposed between the thermal resist mask and the pixel mask.

11. The shadow mask module according to claim 10, further comprising a third thermal insulating adhesive layer disposed between the pixel mask and the first frame.

12. The shadow mask module according to claim 2, further comprising a cooling tube disposed in the first frame and used for transferring a cooling material to cool the first frame.

13. The shadow mask module according to claim 1, wherein the thermal resist mask further comprises a mask part and a frame part formed as a unity, and a thickness of the frame part is larger than a thickness of the mask part.

14. The shadow mask module according to claim 13, wherein the pixel mask is fixed on the frame part.

15. The shadow mask module according to claim 1, further comprising a thermal insulating layer disposed on a surface of the thermal resist mask opposite to the gas outlet.

16. The shadow mask module according to claim 1, wherein each second opening is larger than each first opening.

17. The shadow mask module according to claim 1, wherein the thermal resist mask is a common mask, and each second opening is disposed corresponding to a plurality of the first openings.

18. An organic vapor deposition apparatus used for depositing an organic material on a substrate, and the organic vapor deposition apparatus comprising:
a gas source used for providing a gas;
a control valve connected to an outlet of the gas source and used for controlling a flow of the gas of the gas source and a switch of the gas source;
a gas shower head aimed at the substrate;
a tube, an end of the tube being connected to the control valve, another end of the tube being connected to the gas shower head, and the tube being used for transferring the gas to the gas shower head; and
a shadow mask module disposed between the gas shower head and the substrate, and the shadow mask module comprising:
a pixel mask disposed between the gas shower head and the substrate, and the pixel mask comprising a plurality of first openings; and
a thermal resist mask disposed between the gas shower head and the pixel mask, and the thermal resist mask comprising a plurality of second openings, wherein each second opening is disposed corresponding to at least one of the first openings.

19. A thermal evaporation apparatus used for evaporating an organic material on a substrate, and the thermal evaporation deposition apparatus comprising:
an evaporation source used for evaporating the organic material; and
a shadow mask module disposed between the evaporation source and the substrate, and the shadow mask module comprising:
a pixel mask disposed between the evaporation source and the substrate, and the pixel mask comprising a plurality of first openings; and
a thermal resist mask disposed between the evaporation source and the pixel mask, and the thermal resist mask comprising a plurality of second openings, wherein each second opening is disposed corresponding to at least one of the first openings.
